(19) United States
(12) Patent Application Publication
(10) Pub. No.: US 2012/0079332 A1
(43) Pub. Date: Mar. 29, 2012

(54) DEVICE FOR SECURING A JTAG TYPE BUS

(75) Inventors: Anthony DOUMENJOU, Cholet (FR); Steeve LEMAHIEU, Cholet (FR); Gaël MACE, Langan (FR); Olivier TEYSSIER, Les Clos des Roches (FR)

(73) Assignee: THALES, NEUILLY SUR SEINE (FR)

(21) Appl. No.: 13/071,803

(22) Filed: Mar. 25, 2011

(30) Foreign Application Priority Data
Mar. 26, 2010 (FR) 10 01225

(51) Int. Cl. G01R 31/3177; G06F 11/25

(52) U.S. Cl. 714/726; 714/E11.155

(57) ABSTRACT

A device to secure a JTAG type bus in its “scan chain” component chaining mode functionality, when several components are connected in series on the JTAG bus, includes a first interface for receiving JTAG signals and a second interface for the JTAG signals originating from a chain of components. The device includes the following modules: a JTAG frame generator module for verifying the continuity of operation of said Bus and components; a module for monitoring the electrical activity of said Bus and components; an alarm module for sending back an alarm detected by the above modules; an alarm module for managing the operating mode of the device; and a security functions activation module AFS.

### CROSS-REFERENCE TO RELATED APPLICATIONS

This application claims priority to foreign French patent application No. FR 10 01225, filed on Mar. 26, 2010, the disclosure of which is incorporated by reference in its entirety.

### FIELD OF THE INVENTION

The object of the invention relates to a device intended to be placed upstream from a set of components connected in series on a JTAG type Bus, for securing access to the Bus and accordingly access to the various components connected onto the Bus.

### BACKGROUND OF THE INVENTION

The security device according to the invention can be used more generally on any type of Bus.

The word “equipment” used in the present description designates an assembly consisting of the Bus and the components chained to this Bus.

The JTAG (Joint Test Action Group) Bus in its component chaining mode, better known in English as a “scan chain”, which corresponds to its implementation in mode, is today a powerful and widely used element during the development, production and maintenance phases of a piece of equipment for facilitating the implementation, diagnostics and updating of the components present on the JTAG chain, i.e. the components communicating with said Bus. However, it has the disadvantage of being very intrusive with regard to the components on board chained to the Bus.

In an environment that is sensitive in terms of confidentiality and integrity, such functionalities can become real security weaknesses when physical access to a component or board is possible. The components currently used in equipment which cannot be considered as “trusted” do not all offer a facility for locking their JTAG interfaces, which poses a real threat to processing and processed data in the Bus components.

Accordingly, one of the solutions known to the prior art consists in “burying” this Bus at the end of the equipment production phase in order to prevent or at least delay access to it and the possibility of altering the components or the data of such components chained to the Bus.

Also known is the implementation of devices that use methods of authentication between the components present on the JTAG Bus and the external device wishing to be connected to it.

The idea of the present invention is based on the use of a security device of the JTAG Bus which will be positioned at the very beginning of the JTAG chain and which will enable the operation of this Bus to be monitored and controlled.

### SUMMARY OF THE INVENTION

The invention provides a device that secures a JTAG type Bus in its scan chain functionality, when several components Ci are connected in series on said JTAG Bus, the security device having at least one interface ES₁ for receiving the JTAG signals and at least one interface ES₂ for the JTAG signals originating from the chain of components, including at least the following modules:
a JTAG frame generator module F1 for verifying the continuity of operation of said Bus and components,
a module F3 for monitoring the electrical activity of said Bus and components,
an alarm module adapted for sending back an alarm detected by the F1 and F3 modules,
a device operating mode management alarm module,
a security functions activation module AFS.

The security device comprises, for example, a module F2 for filtering commands sent on the JTAG Bus.

It may comprise a multiplexer M which receives an activation signal from the module AFS, and said multiplexer M handles concurrent access to the JTAG Bus between the commands originating from Outside and those transmitted by the frame generator module F1.

The invention also relates to a method of securing operation of a JTAG Bus characterized in that it implements the security device DS having the aforementioned characteristics.

In a standby mode, for each change of state of any of the signals tckExt, tmsExt, tdiExt and tdoExt, tckCh, tmsCh, tdiCh and tdoCh of the JTAG Bus, the method according to the invention activates an alarm signal.

According to another mode of implementation for the method and when the security device according to the invention receives the four signals tckExt, tmsExt, tdiExt and tdoExt, tckCh originating from a JTAG port (ES₁, ES₂) of the equipment including the Bus and the components, the method filters the JTAG commands according to the set of instructions enabled by the operating mode of a component.

In one of the following modes: unlocked factory mode, locked factory mode, locked maintenance or unlocked maintenance mode, at each instruction not belonging to the set of instructions enabled and present on the JTAG port symbolized by the inputs ES₁, ES₂, at the input of the security device, the latter activates a “forbidden_command” alarm.

The method may comprise a step during which the integrity of the JTAG Bus is tested and in which said step comprises
a frame transmission by the frame modulator F1, after activation of the module F1 via the security functions activation module AFS with a signal testing the chain composed of the components, said frames including the signals corresponding to the JTAG signals TCK_gen, TMS_gen, TDI_gen;
the module F1 in return receives information originating from the chain of components and will transmit signals on the one hand to the module AFS, namely the result of the chain test, an error signal if the frame generator F1 has decreed an error in the operation of a component and the tdo_Ext data to the interface ES₁.

### BRIEF DESCRIPTION OF THE DRAWINGS

Additional aspects, characteristics and advantages of the invention will become more readily apparent by reading the detailed description that follows, given by way of illustration and in no way restrictive, accompanied by figures, which represent:

FIG. 1, an example of the architecture of the JTAG chain security system using the device according to the invention,

FIG. 2, an example of the internal architecture of the device according to the invention within the context of using an FPGA, and

FIG. 3, a diagram of the state of the operating modes of the security device according to the invention.

### DETAILED DESCRIPTION

For purposes of description herein, the example that follows is given within the context of a JTAG Bus, but it will be understood that the invention extends to any type of Bus with similar functionalities to those of the JTAG Bus.

As a reminder, the JTAG Bus is a synchronous serial Bus composed of the following five control signals:
TMS (Test Mode Select) for the JTAG communication activation signal,
TCK (Test Clock) for the Clock,
TDI (Test Data Input) for Data Input,
TDO (Test Data Output) for Data output,
TRST (Test ReSet) for resetting. This optional signal is active-low.

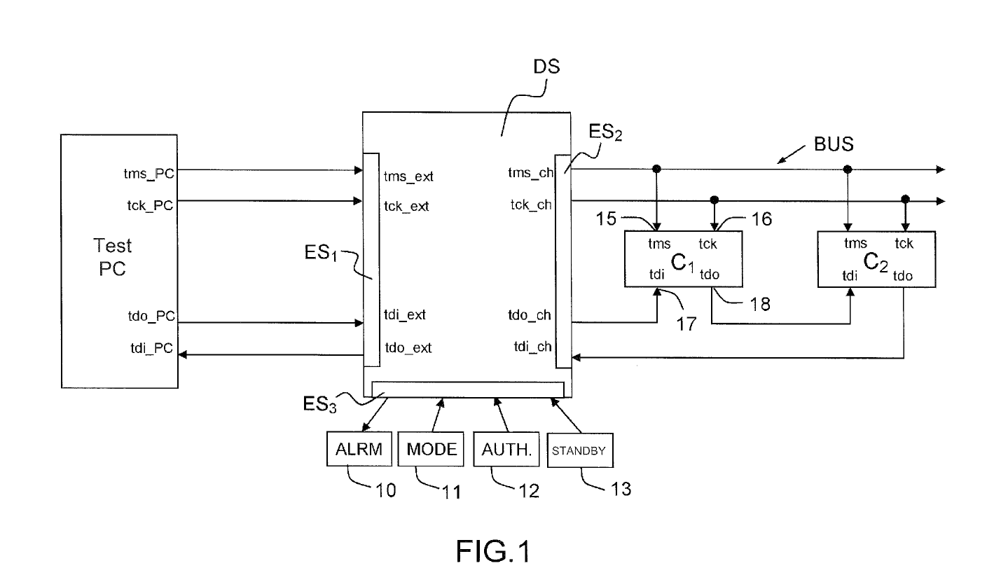

FIG. 1 represents an architectural view of the JTAG chain security system using the security device DS according to the invention.

The security device according to the invention is placed at the input of a JTAG Bus on which N components Ci can be connected.

The functionality of the security device according to the invention comprises, for example, one or more of the following modules:
monitoring of activity on the JTAG Bus,
filtering of commands passed on the JTAG chain according to the authentication level and the phase of life of the equipment,
integrity test of the JTAG chain,
management of alarms associated with the activity of the JTAG Bus.

In FIG. 1, three physical input/output interfaces ES₁, ES₂, ES₃ are depicted for enabling the security device according to the invention to communicate with the outside.

In the case of an embodiment in FPGA (Field Programmable Gate Array) type programmable technology, the security device according to the invention DS will also comprise an interface for its own programming, the clock signal and the reset signal of the FPGA, as well as the power supply signal in the case where the security device according to the invention does not have its own power supply.

The JTAG signals coming from outside have references with the suffix Ext. Hence there are the following signals on the input/output interface ES₁: TCK_ext, TMS_Ext, TDI_Ext, TDO_Ext corresponding respectively to the Clock, JTAG communication activation signal, Data Input and Data output signals. These signals may originate from a device other than a test PC.

The signals originating from the chain on which the different components Ci are connected have references with the suffix CH and are found on the input/output interface ES₂. These signals are: TCK_CH, TMS_CH, TDI_CH and TDO_CH corresponding respectively to the Clock, JTAG communication activation signal, Data Input and Data output signals relating to the components Ci.

The description will use either upper case or lower case to designate the aforementioned signals.

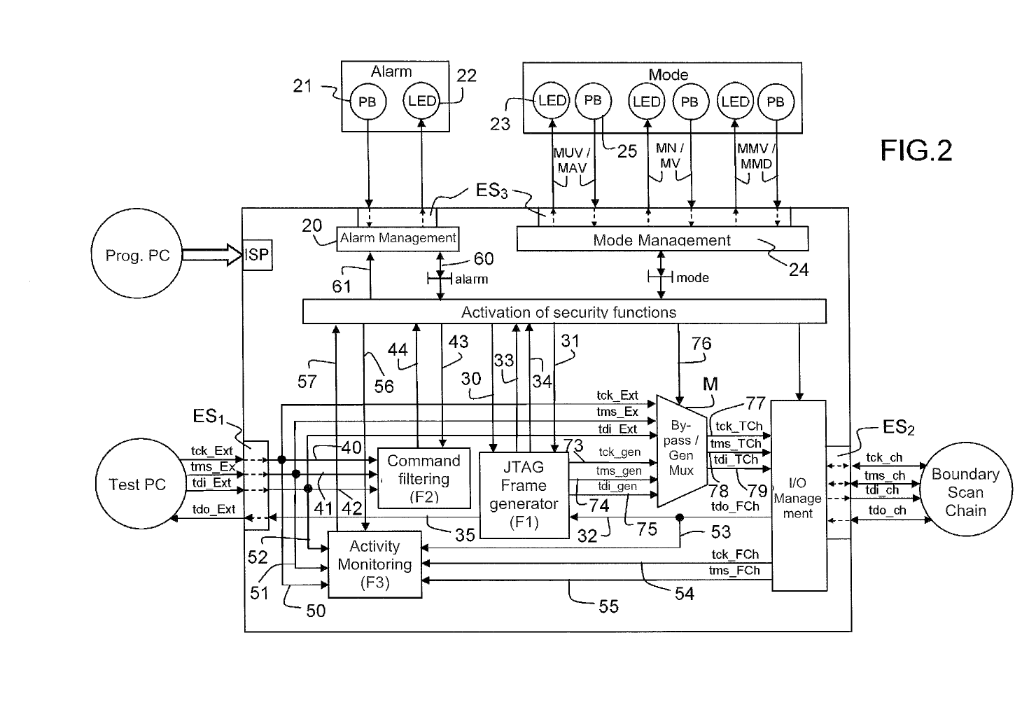

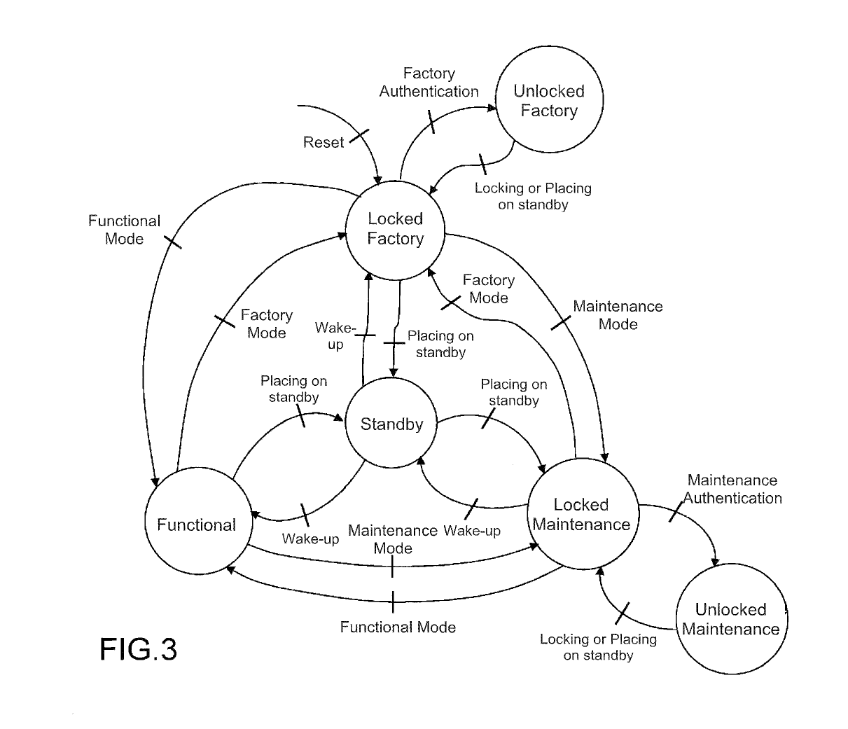

Input/output ES₃ will provide an interface with, for example, an alarm management module 10, a management module 11 for the security device's mode of use, examples of mode being given in FIGS. 2 and 3, an authentication module 12, a standby module 13.

Each of the components Ci connected to the JTAG Bus includes an input 15 for tms signals, an input 16 for tmi signals, an input 17 for tck signals and an output 18 for tdo data signals in the direction of another component CN+1.

FIG. 2 depicts the components and modules of the security device, as well as their interactions with the chain of components and the alarm management modules.

At the first interface ES₁ in FIG. 2 are the JTAG Bus signals originating from outside: TCK_ext, TMS_Ext, TDI_Ext, TDO_Ext. The signals may originate from a test PC or from any other means.

A second interface ES₂ is used for dialogue with the different components of the “boundary scan” chain.

A third interface ES₃ is used to connect, for example, a first alarm management module 20, in conjunction with a push-button 21 which can notably be used for a reset or the deactivation of an alarm, an LED 22 triggered by an alarm indicating a malfunction in the operation of the JTAG Bus chain components.

The interface ES₃ is also used to interface a mode management module 24 with the security device. The mode management module will manage the operating modes of the security device according to the invention, as will be explained below. The access, the activation of one mode or another will be effected by using, for example, a push-button 25, which activity will be indicated by an LED 26.

The security device DS according to the invention includes, for example:
a module F1 for generating JTAG frames which are used for verifying the continuity of the JTAG Bus, i.e. the correct connection of the different components on the Bus and the authenticity of the components which are connected to it. For this, the module F1 regularly or on demand transmits command frames to the chain of components for ensuring the completeness and integrity of the responses of the component(s) addressed on the Bus. The JTAG commands used for this purpose, such as those defined in the JTAG standard as IDCODE or USERCODE, can be used to retrieve the contents of registers available at the level of the JTAG controller of each component connected to the Bus, said registers being able to contain the identifier of the component manufacturer, that of the factory making the equipment, or even a cryptographic signature for checking the authenticity of the component;
a module F2 for filtering commands passing on the Bus;
a module F3 for monitoring the electrical activity on the Bus according to a given mode of operation;
the alarm module 20 and the mode management module 24.

The different modules implemented in the security device according to the invention are interconnected as described below.

The frame generator module F1 receives signals from a security functions activation module AFS, e.g. a chain test start or stop signal 30, a reset signal 31 from the security functions activation module AFS. It also receives information 32 originating from the chain of components, better known in English by the term “Chain Boundary Scan”, via an input/output management module GIO. It will transmit signals on the one hand to the module AFS, namely the result of the chain test 33, an error signal 34 if the frame generator has decreed an error in the operation of a component and it transmits the tdo_Ext data to the interface ES1. The frame generator will generate signals 36, 37, 38 corresponding to the JTAG signals TCK_gen, TMS_gen, TDI_gen, which can be used to test the operation of a component, or its correct connection to the JTAG Bus.

Module F2 is a command filtering module. It receives the different JTAG signals 40, 41, 42 respectively TCK_ext, TMS_Ext, TDI_Ext from a test PC for example, a signal 43 originating from the AFS and corresponding to a command filtering function start signal from the AFS module. It transmits a signal 44 to the module AFS which sends back an alarm activation signal in the event that the command to a component of the chain should not be enabled. For this, the module may have a table including the commands enabled as well as a module for comparing the command signals received and the enabled commands stored.

Module F3 will receive the JTAG signals originating from outside 50, 51, 52 respectively TCK_ext, TMS_Ext, TDI_Ext and the JTAG signals 53, 54, 55 respectively tdo_ch, tck_ch, tms_ch originating from the chain of components. F3 also receives the signal 56 from the module AFS for starting or stopping the electrical activity monitoring functions and sends back to this same module an activity detection signal 57 which will be interpreted according to the context, the operating mode of the Bus.

The device DS also includes a multiplexer M which receives an activation signal from the module AFS. The multiplexer M is used to manage concurrent access to the JTAG Bus between the commands originating from Outside and those transmitted by the frame generator F1. This multiplexer M is, for example, called upon during the Bus continuity monitoring mode.

The alarm module 20 receives alarm signals from the AFS in the event of any anomaly detected (unexpected activity, forbidden command, etc.) and sends back alarm acknowledgement signals for indicating alarm handling, for example.

The mode or mode management module 24 is used to indicate to the JTAG Bus security module the current state in the life cycle of the equipment. For example, normal mode MN, standby mode MV, factory authentication mode MAU, locked factory mode MUV, locked maintenance mode MMV or unlocked maintenance mode MMA or authentication maintenance. Details of these modes will be given further on in the description.

The JTAG Bus security device DS according to the invention activates its monitoring tasks according to the operating mode in which it functions.

According to this mode, for example, the security device according to the invention:
either allows the JTAG set of instructions corresponding to a selected mode to pass and filter the rest of the JTAG instructions,
or monitors activity on the Bus.

It is also adapted for testing the integrity of the chain (continuity of the chain and identification of the components Ci).

In parallel, the device according to the invention will manage the change of operating mode signals of the device and the alarm.

An operating mode is defined by the combination of the life cycle of the component and a preliminary authentication state of the operator wishing to use the JTAG Bus.

The security device according to the invention will, for example, manage the following seven operating modes:
Reset,
Locked factory,
Unlocked factory,
Normal,
Standby,
Locked maintenance,
Unlocked maintenance.

Reset Mode: the internal logic (state machines, switches) of the security device DS according to the invention is set in a known state. The inputs/outputs ES₁ and ES₂ managed by the device DS are in a known state. The device according to the invention is in Reset mode when the “Reset_device” signal is set to the logic state.

Locked Factory Mode MUV: the device DS according to the invention filters the set of instructions in factory mode (only the instructions IDCODE, USERCODE; USER1, USER2 known in the JTAG standard are enabled). It also monitors the Bus when it is inactive for detecting an intrusion internal to the chain. It raises an alarm if it detects a forbidden instruction on the Bus.

The instructions listed correspond at least to those described in the standard IEEE 1149.1-2001 (R2008). They may also include special instructions implemented by the manufacturers of the components making up a JTAG controller, although such instructions must still respect a format defined by the standard.

Normal Mode MN: the device DS according to the invention filters the set of instructions in normal mode. It also monitors the Bus when it is inactive for detecting an intrusion internal to the chain. It raises an alarm if it detects a forbidden instruction on the Bus.

These commands are given as a guide: the list of commands to be used is dependent on the context of the implementation of the device. Without going outside the scope of the invention, it is possible to use other instructions.

Standby Mode MV: the device according to the invention is powered by battery while the other components of the JTAG chain are not powered. The device according to the invention monitors activity on the Bus and raises an alarm if it detects a change of state on one of the Bus signals.

Locked Maintenance Mode MMV: the security device according to the invention completely filters the commands passed on the JTAG Bus (no command is enabled). It raises an alarm if it detects an instruction on the Bus.

Unlocked Maintenance Mode MMD: the device according to the invention filters in functional mode (e.g. only the instructions IDCODE, USERCODE and USER1 are enabled). It also monitors the Bus when it is inactive for detecting an intrusion internal to the chain. It raises an alarm if it detects a forbidden intrusion on the Bus.

FIG. 3, shows a state-transition diagram of the different function modes of the security device according to the invention.

The functionalities are set out in Table 1 below:

TABLE 1

| Operating | | | | |
|---|---|---|---|---|
| phase | State | F1 | F2 | F3 |
| Factory | Locked | Yes | No | Yes |
| Factory | Unlocked | Yes | Yes | Yes |
| Normal | Locked | Yes | Yes | Yes |
| Standby | Locked | No | No | Yes |
| Maintenance | Locked | Yes | No | Yes |
| Maintenance | Unlocked | Yes | Yes | Yes |

The integrity test is performed at least once at the start-up of the equipment. It forms an integral part of the self-test.

When the system is in unlocked mode, i.e. it has had authentication from the user, then the security device according to the invention carries out monitoring when there is no command passed (verification that any command passed originates from the JTAG Bus).

Monitoring the JTAG Bus

The security device according to the invention receives the signals (tckExt, tmsExt, tdiExt and tdoExt) originating from the JTAG port of the equipment consisting of the Bus and components, and the JTAG signals (tckCh, tmsCh, tdiCh and tdoCh) originating from the JTAG Bus chaining certain components Ci of the equipment. In standby mode, the components chained on the JTAG Bus are not powered. They act like open circuits on the Bus. In this mode, the monitoring of the JTAG Bus is used to detect any intrusion attempt either on the JTAG port of the equipment, or on one of the components present on the chain and which would be powered correctly.

In the other modes, the monitoring function is active in the absence of an enabled command present on the ES₁ and ES₂ ports of the security device. In these modes, the monitoring function is used to detect any direct intrusion on the JTAG Bus.

In this mode, a command present on the interface ES₁ characterizes an intrusion from outside the JTAG chain. A command present on the interface ES₂ characterizes an intrusion from inside the JTAG chain. On this latter point, monitoring on the ES₂ port takes place outside of the integrity and continuity test times.

Standby Mode

Monitoring the JTAG Bus in STANDBY mode.

At each change of state of any of the signals tckExt, tmsExt, tdiExt and tdoExt, tckCh, tmsCh, tdiCh and tdoCh the security device according to the invention must raise an alarm (e.g. “activity_detection_not_enabled” activation) and light the LED or any other equivalent “alarm” device.

Modes Other than Standby

Command Filtering on the JTAG Bus

The security device according to the invention receives the four signals tckExt, tmsExt, tdiExt and tdoExt, tckCh originating from the JTAG port (ES₁, ES₂) of the equipment. It is thus capable of analysing these signals and deducing from them the commands passed on the Bus. The aim is notably to filter the JTAG commands according to the set of instructions enabled by the operating mode of the component.

Locked Factory and Locked Maintenance Modes

Command filtering on the JTAG Bus in the locked Factory and locked Maintenance modes.

In these modes, command filtering is total. No command should be passed on the Bus. At each instruction detected on the JTAG port at the input of the security device according to the invention, the latter must, for example, raise a “forbidden_command” alarm and light the “alarm” LED.

Unlocked Factory Mode

Command filtering on the JTAG Bus in the unlocked factory mode.

In this mode, the enabled set of instructions includes, for example, the following instructions: IDCODE, USERCODE, EXTEST, USER1, USER2, USER3. At each instruction not belonging to the set of instructions enabled and present on the JTAG port at the input of the security device according to the invention, the latter must raise a “forbidden_command” alarm and light the “alarm” LED.

Unlocked Maintenance Mode

Command filtering on the JTAG Bus in the unlocked Maintenance mode.

In this mode, it is possible to use the following enabled set of instructions: IDCODE, USERCODE, EXTEST. At each instruction not belonging to the set of instructions enabled and present on the JTAG port at the input of the security device according to the invention, the latter must raise a “forbidden_command” alarm and, for example, light the “alarm” LED.

Functional Mode

Command filtering on the JTAG Bus in the Functional mode.

In this mode, the enabled set of instructions includes, for example, the following instructions: IDCODE and USERCODE. At each instruction not belonging to the set of instructions enabled and present on the JTAG port at the input of the security device according to the invention, the latter must, for example, raise a “forbidden_command” alarm and light the “alarm” LED.

Standby Mode

Command filtering on the JTAG Bus in standby mode.

The command filtering function must not raise any alarm in the standby mode.

JTAG Bus Integrity Test

The security device according to the invention tests the integrity of the JTAG Bus at least at each start-up of the equipment. Through the implementation of the module F3, it provides a chain continuity test (to verify that the chain is not broken) and verifies the authenticity of the components present on the chain in order to verify their authentication. Authentication is based, for example, on a simple verification of the identifiers returned in response to the instructions IDCODE and USERCODE from the components.

All Modes Except the Standby Mode

JTAG Bus Continuity Test in all Modes Except the Standby Mode

The security device according to the invention programs all the JTAG Bus components in bypass and sends, for example, an IDCODE frame on the tdoCh signal. It must receive this same frame on the tdiCh signal after a number of clock periods corresponding to the number of components present on the chain. If it does not receive the correct frame, the security device according to the invention will raise a “chain_error” alarm and, for example, light the “alarm” LED.

JTAG Bus Component Identification Test in all Modes Except the Standby Mode

The security device according to the invention programs all the JTAG Bus components with the IDCODE and USERCODE request instructions and retrieves the data on the tdoCh signal corresponding to the IDCODEs and USERCODEs of the Bus components. It then verifies the consistency between the base IDCODEs and USERCODEs and the retrieved IDCODEs and USERCODEs. If there is a difference, the security device according to the invention, raises a “chain_error” alarm and lights the “alarm” LED.

Standby Mode

JTAG Bus Integrity Test in the Standby Mode

No alarm is raised.

The function REQ-MOI known in the JTAG standard is deactivated in the standby mode.

Management Mode

The security device according to the invention receives the signals indicating the mode in which the basic system is situated (modes described in the diagram in FIG. 3). It interprets these signals for updating the operating mode. This datum is useful to the security device according to the invention for knowing which function it has to activate.

Management of the System Operating Modes

The security device according to the invention updates the shared variable Modeimage of the system operating mode from the Factory/Auth, Maintenance/Auth and Normal/Standby signals.

Alarm Management

The security device DS according to the invention has three abnormal behaviour detection functions on the JTAG Bus. At each detection of a behaviour of this type (activation of the “activity_detection”, “forbidden command” or “chain-error” signals), it must activate an alarm. The user, after acknowledging this alarm, can reinitialize using the “alarm_reset” signal.

Alarm Management

The security device according to the invention updates the shared variable Alarm which controls the LED of the same name according to the “alarm_set” and “alarm_reset” signals.

Activation of the Security Functions

Based on the shared variable Mode, the security device according to the invention must activate one or more of its three security functions and generate the control signal of the multiplexer used to let the JTAG flow pass or to take over the Bus. It must also retrieve any anomalies detected by these functions and activate the “alarm_set” signal alarm.

The security device according to the invention must activate the security functions according to the operating mode of the system.

It must also be adapted to activate the alarm when one of its security functions reports abnormal behaviour on the Bus.

According to a variant embodiment, the security device DS according to the invention includes an interface ISP connected to a programmable PC that can be used to program the modules of the security device according to the invention.

The security device according to the invention enables this Bus to be used even during the operational phases of the equipment. It provides a self-test at the start-up of the equipment. It allows a regular diagnostic report or one at the request of certain components. It permits extended maintenance test functions and possible reprogramming of the component. It offers additional features to the interface locking functionalities present on certain components.

What is claimed is:

1. A device for securing a joint test action group (JTAG) type bus in a scan chain component chaining mode functionality of the JTAG bus when components are connected in series on said JTAG Bus, said device including at least one interface ES₁ for receiving JTAG signals and at least one additional interface ES₂ for the JTAG signals originating from the chain of components, said device comprising:
a JTAG frame generator module for verifying the continuity of operation of said bus and components;
a module for monitoring the electrical activity of said bus and components;
an alarm module for sending back an alarm detected by the JTAG frame generator module and the module for monitoring the electrical activity of said bus and components;
an alarm module for managing the operating mode of the device; and
a security functions activation module.

2. The device of according to claim 1, further comprising a module for filtering commands passed on the JTAG Bus.

3. The device according to claim 1, further comprising a multiplexer which receives an activation signal from the security functions activation module, said multiplexer handling concurrent access to the JTAG bus between commands originating from outside and commands transmitted by the frame generator module.

4. The device to claim 2, further comprising a multiplexer which receives an activation signal from the security functions activation module, said multiplexer handling concurrent access to the JTAG bus between commands originating from outside and commands transmitted by the frame generator module.

5. A method of securing operation of a JTAG bus implementing the security device according to claim 1.

6. A method of securing operation of a JTAG bus implementing the security device according to claim 4, wherein when in a standby mode, for each change of state of any of signals TCK_Ext, TMS_Ext, TDI_Ext, TDO_Ext corresponding to clock signals, communication activation signal, data input and data output and JTAG bus signals originating from outside TCK_Ext, TMS_Ext, TDI_Ext, TDO_Ext and tdoCh of the JTAG Bus, the method activates an alarm signal.

7. A method of securing operation of a JTAG bus implementing the security device according to claim 1, comprising receiving four signals TCK_Ext, TMS_Ext, TDI_Ext, TDO_Ext originating from one of the JTAG ports ES₁, ES₂ of the equipment including the bus, and the components and filters the JTAG commands according to a set of instructions enabled by the operating mode of a component.

8. The method according to claim 5, wherein, in one of the following modes: unlocked factory mode, locked factory mode, locked maintenance mode, and unlocked maintenance mode, at each instruction not belonging to a set of instructions enabled and present on the JTAG ports ES₁, ES₂ at the input of the security device, the security device activates a forbidden_command alarm.

9. The method according to claim 5, further comprising a step during which the integrity of the JTAG Bus is tested, said step comprising:
a frame transmission by the frame modulator F1, after activation of the module F1 via the security functions activation module with a signal testing the chain including the components, said frames including signals generated by the frame generator corresponding to JTAG signals TCK_gen, TMS_gen, TDI_gen, said signals used to test operation of a component or JTAG bus connection; and
the frame generator module in return receiving information originating from the chain of components and transmitting signals, on the one hand, to the security functions activation module, namely the result of the chain test, and an error signal if the frame generator has decreed an error in the operation of a component and it transmits the tdo_Ext data to the interface ES₁.
